(19) United States
(12) Patent Application Publication
(10) Pub. No.: US 2010/0314725 A1
(43) Pub. Date: Dec. 16, 2010

(54) Stress Balance Layer on Semiconductor Wafer Backside

(75) Inventors: Shiqun Gu, San Diego, CA (US); Arvind Chandrasekaran, San Diego, CA (US); Urmi Ray, Ramona, CA (US); Yiming Li, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/483,759

(22) Filed: Jun. 12, 2009

(51) Int. Cl. H01L 23/00; H01L 21/306; H01L 21/31

(52) U.S. Cl. 257/635; 257/632; 438/700; 438/778; 257/E23.002; 257/E21.215; 257/E21.24

(57) ABSTRACT

A semiconductor component (such as a semiconductor wafer or semiconductor die) includes a substrate having a front side and a back side. The semiconductor die/wafer also includes a stress balance layer on the back side of the substrate. An active layer deposited on the front side of the substrate creates an unbalanced stress in the semiconductor wafer/die. The stress balance layer balances stress in the semiconductor wafer/die. The stress in the stress balance layer approximately equals the stress in the active layer. Balancing stress in the semiconductor component prevents warpage of the semiconductor wafer/die.

### TECHNICAL FIELD

The present disclosure generally relates to integrated circuits (ICs). More specifically, the present disclosure relates to manufacturing integrated circuits.

### BACKGROUND

Semiconductor dies include collections of transistors and other components. Commonly, these substrates are semiconductor materials, and, in particular, silicon. Additionally, these substrates are conventionally thicker than necessary to obtain desirable device behavior. The semiconductor dies are singulated or diced from a semiconductor wafer.

Thick substrates have advantages during semiconductor manufacturing outside of transistor behavior. During manufacturing of wafers and/or dies, a substrate endures dozens of processes, high temperatures, and transfers between tools or even fabrication sites. During these transfers the substrate can break, resulting in a loss of time and resources. Thick substrates are less likely to break during manufacturing.

Additionally, the materials deposited on the substrate have a different stress than the substrate resulting in unbalanced stress. When the stress between the substrate and deposited materials is unbalanced, the substrate may warp or bend to reach an equilibrium stress. Thick substrates are able to counterbalance the stress imposed by deposited materials better than thin substrates. Problems with using thin substrates during manufacturing have conventionally been solved by attaching the thin substrate to a thick support substrate by adhesives. The support substrate is referred to as a carrier wafer. The carrier wafer is detached after completion of the portions of the manufacturing process during which the thin substrate is at risk of fracturing.

Use of a carrier wafer is undesirable for several reasons. The carrier wafer adds cost to manufacturing but does not add tangible value to the final product. Additionally, the adhesives that attach the carrier wafer to the thin substrate leave residue on the thin substrate of the semiconductor wafer. Although the carrier wafer provides stability during manufacturing, releasing the thin substrate from the carrier wafer represents a manufacturing challenge.

One example of manufacturing using a thin substrate is construction of stacked ICs. Stacked ICs increase device functionality and decrease die size by stacking dies vertically. Similar to high-rise towers that fit more office space in a smaller land area, stacked ICs offer more space for transistors and other components while occupying the same area.

In stacked ICs, a second die is stacked on a first die allowing construction to expand into three dimensions (3D). Stacked ICs allow products with a greater number of components to fit in small form factors. Component density of a semiconductor die is number of components in the die divided by the die area. For example, stacking a die on an identical die results in approximately double the number of components in the same area to double component density. When a second die is stacked on a first die, the two dies share the same packaging and communicate to external devices through the packaging.

Conventionally, the second die is coupled to packaging and external devices with through silicon vias located in the first die. Through silicon vias are limited in aspect ratio based, in part, on the manufacturing technique selected. As a result, the height of the first die is limited in order to ensure the through silicon via may extend the entire height of the first die. The through silicon via should extend the entire height to obtain a conducting path from a packaging substrate to the second die. As the height of the first die decreases to accommodate the through silicon via manufacturing, the first die loses structural strength.

Manufacturing a stacked IC conventionally includes attaching a first wafer (containing many dies) to a carrier wafer for support before thinning the dies/wafer. The first wafer is then thinned to accommodate the height of the through silicon vias. The first wafer (containing the dies) needs to be released from the carrier wafer after thinning to package the stacked IC. However, once released from the carrier wafer, the first wafer or die may have an unbalanced stress between the substrates of the first dies and any active layers in the dies.

Thus, there is a need for balancing the stress between layers on a wafer/die.

### BRIEF SUMMARY

According to one aspect of the disclosure, a semiconductor component includes a first substrate having a front side and a back side. The semiconductor component also has a stress balance layer on the back side. The stress balance layer balances stress in the semiconductor die.

According to another aspect of the disclosure, a method of manufacturing a semiconductor wafer includes thinning the semiconductor wafer. The method also includes depositing a stress balance layer on a backside of the semiconductor wafer after thinning the semiconductor wafer. The method further includes releasing the semiconductor wafer from a carrier wafer after depositing the stress balance layer.

According to yet another aspect of the disclosure, a semiconductor component includes a substrate having a front side and a back side. The semiconductor component also includes an active layer on the front side. The active layer imposing stress on the substrate. The semiconductor component further includes means for balancing stress imposed by the active layer. The balancing means being disposed on the back side of the substrate.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a block diagram showing an exemplary wireless communication system in which an embodiment of the disclosure may be advantageously employed.

FIG. 2 is a block diagram illustrating a design workstation used for circuit, layout, and logic design of a semiconductor component as disclosed below.

FIG. 3 is a cross-sectional view illustrating a stacked IC.

FIG. 4 is a cross-sectional view illustrating a die under tensile stress.

FIG. 5 is a cross-sectional view illustrating an exemplary wafer having a stress balance layer according to one embodiment.

FIG. 6 is a flow chart illustrating a method of manufacturing an exemplary wafer having a stress balance layer according to one embodiment.

FIG. 7 is a flow chart illustrating a method of manufacturing an exemplary wafer with through silicon vias having a stress balance layer according to one embodiment.

FIGS. 8A-8F are cross-sectional views illustrating manufacturing an exemplary semiconductor wafer having a stress balance layer according to one embodiment.

### DETAILED DESCRIPTION

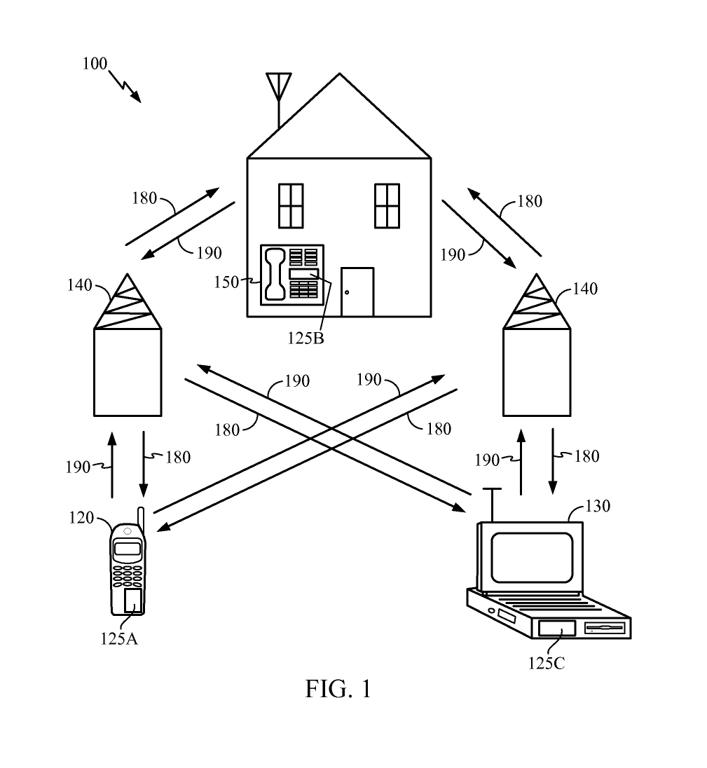

FIG. 1 is a block diagram showing an exemplary wireless communication system 100 in which an embodiment of the disclosure may be advantageously employed. For purposes of illustration, FIG. 1 shows three remote units 120, 130, and 150 and two base stations 140. It will be recognized that typical wireless communication systems may have many more remote units and base stations. Remote units 120, 130, and 150 include IC devices 125A, 125B and 125C, that include circuitry manufactured by the processes disclosed here. It will be recognized that any device containing an IC may also include semiconductor components having the disclosed features and/or components manufactured by the processes disclosed here, including the base stations, switching devices, and network equipment. FIG. 1 shows forward link signals 180 from the base station 140 to the remote units 120, 130, and 150 and reverse link signals 190 from the remote units 120, 130, and 150 to base stations 140.

In FIG. 1, remote unit 120 is shown as a mobile telephone, remote unit 130 is shown as a portable computer, and remote unit 150 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 1 illustrates remote units according to the teachings of the disclosure, the disclosure is not limited to these exemplary illustrated units. The disclosure may be suitably employed in any device which includes semiconductor components, as described below.

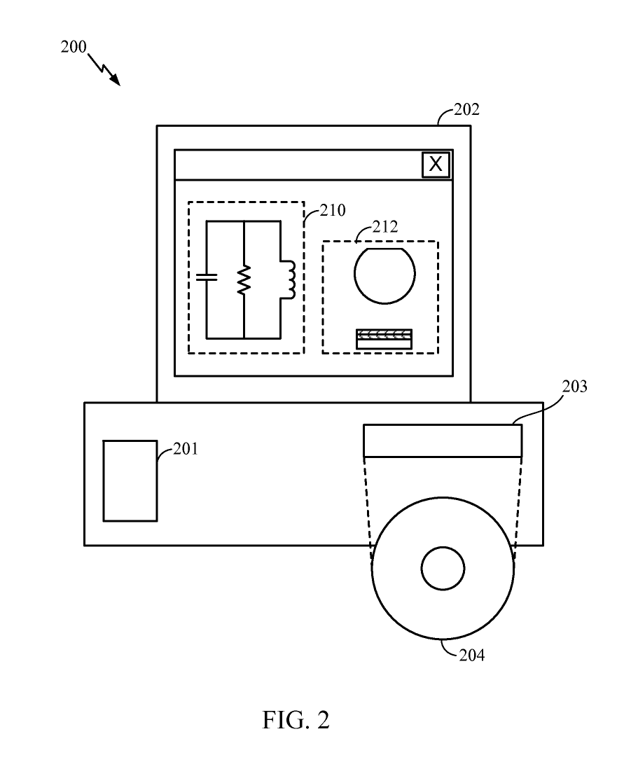

FIG. 2 is a block diagram illustrating a design workstation used for circuit, layout, logic, wafer, die, and layer design of a semiconductor part as disclosed below. A design workstation 200 includes a hard disk 201 containing operating system software, support files, and design software such as Cadence or OrCAD. The design workstation 200 also includes a display to facilitate design of a semiconductor part 210 that may include a circuit, a semiconductor wafer, a semiconductor die, or layers contained within a semiconductor wafer or semiconductor die. A storage medium 204 is provided for tangibly storing the semiconductor part 210. The semiconductor part 210 may be stored on the storage medium 204 in a file format such as GDSII or GERBER. The storage medium 204 may be a CD-ROM, DVD, hard disk, flash memory, or other appropriate device. Furthermore, the design workstation 200 includes a drive apparatus 203 for accepting input from or writing output to the storage medium 204.

Data recorded on the storage medium 204 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 204 facilitates the design of the circuit design 210 or the semiconductor component 212 by decreasing the number of processes for designing semiconductor wafers.

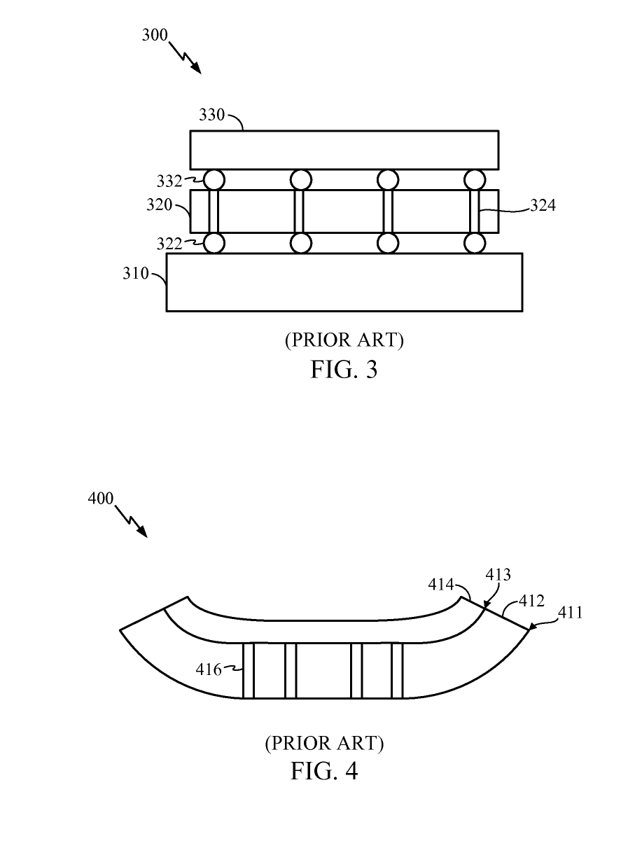

FIG. 3 is a cross-sectional view illustrating a stacked IC. A stacked IC 300 includes a packaging substrate 310. The packaging substrate 310 is coupled to a first tier die 320 through a packaging connection 322 such as bumps in a ball grid array. Alternatively, pins or other suitable packaging connections may be used. A second tier die 330 is coupled to the first tier die 320 through an electrical connection 332 such as metal to metal bonding. The first tier die 320 includes through silicon vias 324. The through silicon vias 324 extend the entire height of the first tier die 320 and couple the packaging substrate 310 to the electrical connection 332 to allow communication from the packaging substrate 310 to the first tier die 320 or the second tier die 330. Additional dies (not shown) may be stacked further on top of the second tier die 330.

Stacked ICs, such as the stacked IC 300, allow manufacturing of higher density ICs through 3D stacking than could be achieved on a 2D IC. For example, the second tier die 330 may be a memory or cache device, and the first tier die 320 may be a processor or other logic circuitry. A large portion of a microprocessor's die area is occupied by L2 cache. Stacking the cache on the logic circuitry may reduce the die size of the microprocessor. Alternatively, DRAM components, located on dies separate from a microprocessor may be stacked on the microprocessor. Stacking DRAM components on a microprocessor may reduce space constraints on a motherboard. Additionally, locating DRAM components closer to the microprocessor may reduce latency and allow use of methods that increase bandwidth to the DRAM components, such as higher clock rates. For at least these reasons, higher densities of components achievable using stacked ICs are expected to support development of future ICs.

When the second tier die 330 is attached to the first tier die 320, damage may occur as a result of the physical force placed on the first tier die 320. The thickness of the first tier die 320 corresponds to its mechanical strength to withstand these physical forces. Thus, when the first tier die 320 is thinned to expose the through silicon vias 324, damage is more likely to occur to the first tier die 320 during attachment of the second tier die 330.

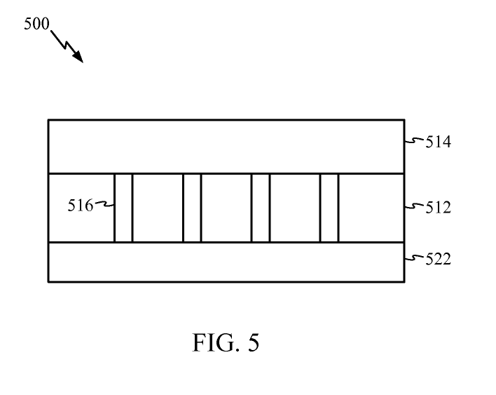

FIG. 4 is a cross-sectional view illustrating a die under tensile stress. A die 400 has a substrate 412 and an active layer 414. The substrate 412 may be, for example, silicon or other semiconductor materials. The active layer 414 may include components such as, for example, transistors. The active layer 414 may also include interconnects and vias to couple the components to external devices (not shown). Through silicon vias 416 are located in the substrate 412 to allow coupling between a front side 413 of the substrate 412 and a back side 411 of the substrate 412. For example, the die 400 may be a first tier in a stacked IC mounted on a packaging substrate (not shown). In this case, the through silicon vias 416 may couple a second tier of the stacked IC to the packaging substrate.

The through silicon vias 416 are formed with etching techniques such as, for example, reactive ion etching, wet etching, or laser drilling. The height of the through silicon vias 416 is limited and determined, in part, by the width of the through silicon vias 416. For example, an etch process may have an etch ratio of 10:1, indicating the etch may only proceed ten times as deep as the through silicon vias 416 are wide. In this case, a 1 μm through silicon via may be etched 10 μm deep. Thus, the height of the substrate 412 should be smaller than that allowed by the selected etching process and the width of the through silicon vias 416. In this case, the height of the substrate 412 should be 10 μm. Problems handling the substrate 412 may occur after thinning the substrate 412 to an appropriate height.

The mechanical strength of the substrate 412 is proportional to the height of the substrate 412. Thus, reducing the height of the substrate 412 to allow the through silicon vias 416 to extend from the front side 413 to the back side 411 reduces the mechanical strength of the substrate 412. The active layer 414 remains a fixed height during thinning of the substrate 412. Thus, the substrate 412 has less strength to support the same level of stresses built up in the active layer 414 regardless of the height of the substrate 412. Stresses in the active layer 414 can be residual compressive or residual tensile depending on the number and type of films of which the active layer 414 is composed. If there is a net residual compressive stress on the substrate 412, the substrate 412 will tend to push outwards and the entire assembly will bend in a frown shape. If there is a net residual tensile stress on the substrate 412, the substrate 412 will tend to push inwards and the entire assembly will bend in a smile shape.

Further, temperature may affect the stress in the active layer 414 and the substrate 412. For example, as temperature rises the different materials may expand at different rates. If the active layer 414 expands at a faster rate than the substrate 412, the substrate 412 may warp due to lack of mechanical strength. Warpage may damage devices in the active layer 414 or cause problems later in manufacturing.

Additionally, components in the active layer 414 are designed to function properly in specific stress ranges. For example, tensile stress in the active layer 414 improves carrier mobility in nFET devices.

In addition to built-up stress in the active layer 414, manufacturing processes damage the front side 413 of the substrate 412. Damage is caused by impact of energetic particles on the substrate 412 during plasma processes such as reactive ion etch and metal deposition. The damage may also be caused by exposure to chemicals used during wet etch or cleaning. When the front side 413 of the substrate 412 is damaged, the stress of the damaged portion is different from the bulk of the substrate 412. These differences in stress lead to additional warpage problems in manufacturing.

Balancing stress between the substrate and the active layer of a die is accomplished by depositing an additional layer on the die. Placing the additional layer on a side of the die opposite the active layer does not interfere with components in the active layer. For example, when the active layer is on a front side of the substrate, a stress balance layer may be deposited on a back side of the substrate. The stress balance layer is stress engineered to balance stresses imposed on the substrate by the active layer. The stress in the stress balance layer is approximately equal to stress in the active layer. The difference in stress should result in an acceptable warpage tolerance.

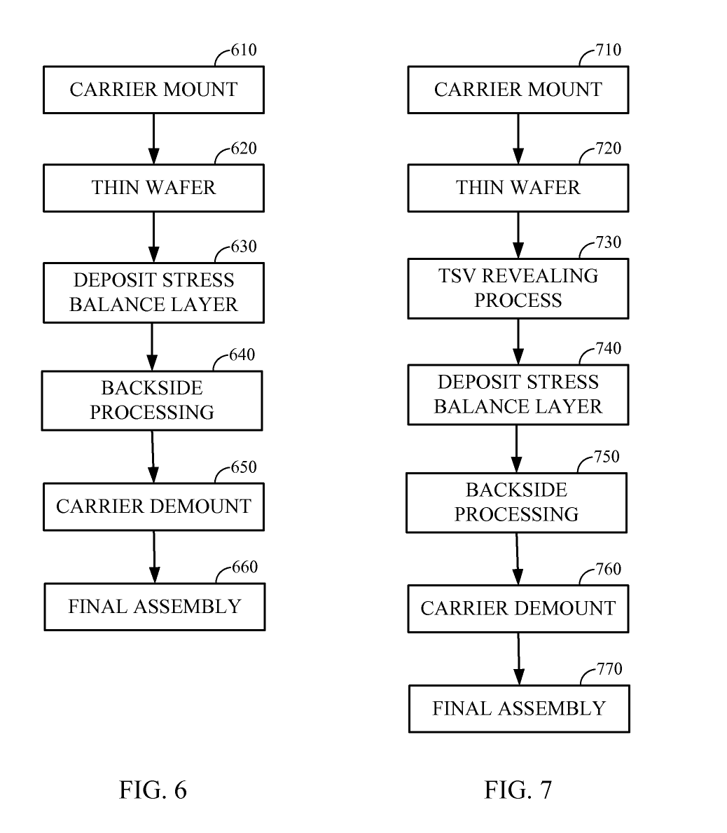

FIG. 5 is a cross-sectional view illustrating an exemplary wafer having a stress balance layer according to one embodiment. A wafer 500 includes a substrate 512. The substrate 512 includes through silicon vias 516. Deposited on the substrate 512 is an active layer 514. The active layer 514 includes components such as transistors or capacitors, interconnects, metal layers, and insulating layers to couple to the components. Although the active layer 514 is illustrated as a single layer, the active layer 514 may be multiple layers of conducting or insulating materials. The conducting or insulating materials may be patterned layers or continuous layers. Stresses from the active layer 514 on the substrate 512 warp the substrate. As the ratio of height of the active layer 514 to the height of the substrate 512 increases stress imbalance increases leading to more warping.

A stress balance layer 522 is deposited on a back side of the substrate 512. Stress of the stress balance layer 522 should be approximately equal to stress in the active layer 514. For example, if the active layer 514 has a tensile stress of 300 MPa, the stress balance layer 522 may have a similar tensile stress of 300 MPa suitable to balance stress of the active layer 514. In this example, tensile stress in the active layer 514 expands along the long axis and elongates the substrate 512 along the same direction. A tensile stress in the stress balance layer 522 elongates along the long axis and assists the substrate 512 in remaining substantially unbent. One example of a material usable for the stress balance layer 522 is silicon nitride. Other examples of materials include silicon carbide, silicon oxide, polymers, or spin on glass.

In the case of using silicon nitride, stress may be controlled across a large range when deposited by plasma enhanced chemical vapor deposition (PECVD). PECVD ion bombardment on the stress balance layer 522 during deposition determines a density of the stress balance layer 522. For example, a background pressure of PECVD deposition may be adjusted to achieve a desired density. Stress is related to density, and therefore, the stress in the stress balance layer 522 may be altered. The quantity and energy of the ions bombarding the stress balance layer 522 during deposition may be controlled by adjusting one or more of gas mixture, deposition rate, temperature, electrode voltages, and deposition pressure. Other materials may be used in the stress balance layer 522. The stress in other materials may be controlled through similar techniques.

According to another embodiment, the stress balance layer 522 may include multiple layers. One example of a multilayer film is [SiO₂/SiN]_{N}. Multilayers have adjustable stress levels by changing the relative thickness of each layer. Additionally, the individual layers of the multilayer film may have their individual stresses controlled through techniques as described above.

Although a stress balance layer may be deposited on a wafer as described above, the stress balance layer may also be applied to individual dies. For example, a semiconductor wafer may be singulated or diced into several semiconductor dies. At least one of the dies cingulated from the wafer may have a stress balance layer deposited as described above.

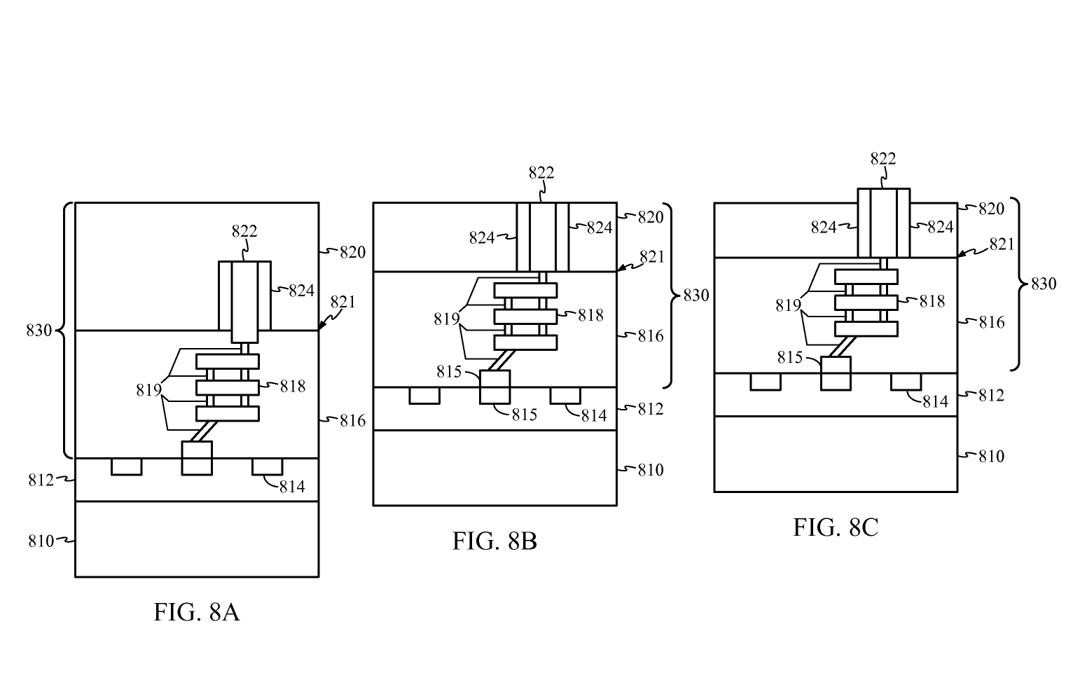

Turning now to FIG. 6 an exemplary process for manufacturing a semiconductor wafer having a stress balance layer is described. FIG. 6 is a flow chart illustrating a method of manufacturing an exemplary wafer having a stress balance layer according to one embodiment. At block 610 a carrier wafer is mounted to a semiconductor wafer. At block 620 the semiconductor wafer is thinned to a desired thickness. At the desired thickness the wafer may be too thin to support active layers on the wafer. As a result, the wafer may warp due to unbalanced stress between the active layers and the wafer. At block 630 a stress balance layer is deposited on a backside of the semiconductor wafer. The stress balance layer is of a thickness and stress that balances the stress on the wafer to prevent warpage. At block 640, additional backside processing on the semiconductor wafer is carried out. Backside processing may include, for example, deposition of a redistribution layer (RDL) or other film layers. At block 650, the carrier wafer is demounted from the semiconductor wafer. Although the term carrier wafer is used, the carrier wafer may be any structure that provides support for the wafer during manufacturing. At block 660, final assembly on the semiconductor wafer is performed including, for example, singulating dies from the semiconductor wafer. Additional processes can be added to the manufacturing flow chart in FIG. 6 to accommodate through silicon vias in the wafer.

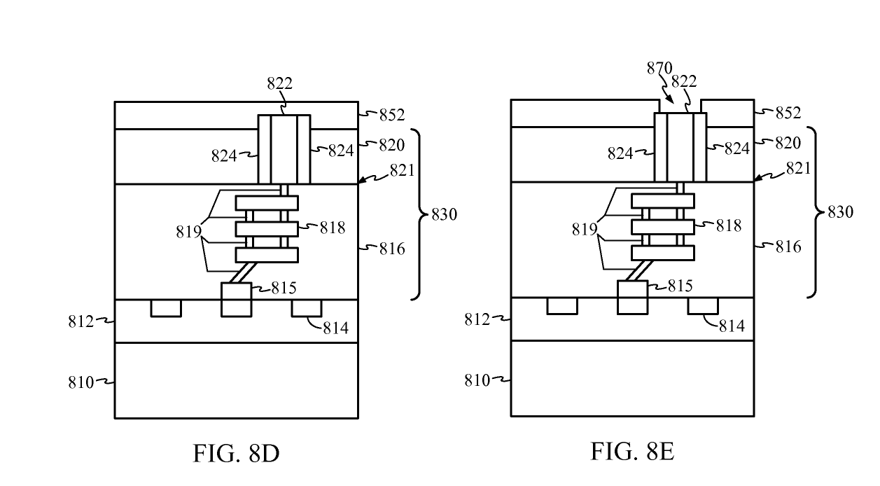

FIG. 7 is a flow chart illustrating a method of manufacturing an exemplary wafer of dies with through silicon vias having a stress balance layer according to one embodiment. At block 710 the semiconductor wafer is mounted to a carrier wafer. At block 720 the semiconductor wafer is thinned. Wafer thinning may be completed, for example, using backgrinding or chemical mechanical polishing.

At block 730, a TSV revealing process is performed such as, for example, a silicon recess etch to expose through silicon vias on a back side of the semiconductor wafer. The recess etch may be accomplished using a reactive ion etch or wet etch that selectively etches silicon at a faster rate than materials in the through silicon via. For example, if the through silicon vias are copper, a reactive ion etch using CF₄ reacts readily with Si on the wafer but not with Cu. A TSV revealing process may not be used in an embodiment having a large via that couples to the TSV. In this embodiment, the via may be disposed on top of the TSV.

At block 740, a stress balance layer is deposited on the backside of the semiconductor wafer. The stress balance layer, in one embodiment, is silicon nitride deposited by PECVD. As described above, the stress and thickness of the silicon nitride layer may be adjusted to obtain balanced stress on the wafer.

At block 750, backside processing on the semiconductor wafer is performed. The backside processing may include, for example, depositing a redistribution layer (RDL) or additional film layers. At block 760, the semiconductor wafer is demounted from the carrier wafer. At block 770, final assembly on the semiconductor wafer is performed including, for example, singulating dies from the semiconductor wafer.

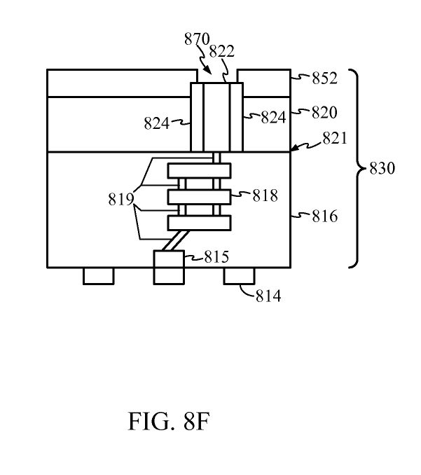

The manufacturing of an exemplary wafer having a stress balance layer is now described in more detail with reference to FIGS. 8A-8E. FIGS. 8A-8E are block diagrams illustrating manufacturing an exemplary wafer having a stress balance layer according to one embodiment.

FIG. 8A is a cross-sectional view illustrating a wafer received for manufacturing according to one embodiment. Attached to a carrier wafer 810 by an adhesive layer 812 is a semiconductor wafer 830. The semiconductor wafer 830 includes dies each having a substrate 820 and an active layer 816 on a front side 821 of the substrate 820. The active layer 816 includes interconnects 818 and vias 819. The active layer 816 may also include additional layers such as insulating layers including silicon oxide or silicon nitride (not shown).

The substrate 820 includes a through silicon via 822 surrounded by an insulating layer 824. The insulating layer 824 prevents shorting of the through silicon via 822 to the substrate 820. Due to manufacturing limitations described above, the through silicon via 822 is not manufactured to extend the entire height of the substrate 820.

The through silicon via 822 couples to the interconnects 818 through one of the vias 819. The interconnects 818 are further coupled to contacts 814 through another one of the vias 819. Through these vias 819 and interconnects 818, a complete electrical path extends from the contacts 814 to the through silicon via 822.

FIG. 8B is a cross-sectional view illustrating a semiconductor wafer after thinning of the wafer according to one embodiment. After thinning the substrate 820, the through silicon via 822 is exposed. In one embodiment, the height of the substrate 820 is approximately 30-50 μm after thinning, which may be selected, in part, on the aspect ratio of the selected etching technique. Thinning may be performed by backgrinding or chemical mechanical polishing.

FIG. 8C is a cross-sectional view illustrating a semiconductor wafer after a recess etch of the dies according to one embodiment. The recess etch further thins the substrate 820. The recess etch removes material in the substrate 820 at a faster rate than material in the through silicon via 822 or the insulating layer 824. In one embodiment, the recess etch is performed by reactive ion etching and/or wet etching.

FIG. 8D is a cross-sectional view illustrating a semiconductor wafer after deposition of a stress balance layer according to one embodiment. A stress balance layer 852 is deposited to cover the substrate 820, the through silicon via 822, and the insulating layer 824. The stress balance layer 852 may be silicon nitride, silicon dioxide, silicon carbide, polymers, or another material preferably having controllable stress. Thin films such as the stress balance layer 852, may be deposited, for example, by PECVD. Stress in the stress balance layer 852 may be controlled, in one embodiment, by controlling composition or ion bombardment during PECVD as described above.

FIG. 8E is a cross-sectional view illustrating a semiconductor wafer after etching openings to through silicon vias according to one embodiment. The through silicon via 822 may be accessed later in semiconductor manufacturing by selectively etching openings 870 in the stress balance layer 852 over the through silicon via 822 to expose the through silicon via 822. For example, photolithography may be used to form an etch mask on the stress balance layer 852. Alternatively, a polishing process exposes the openings 870 to the through silicon via 822.

FIG. 8F is a cross-sectional view illustrating a semiconductor wafer after detachment from the carrier wafer according to one embodiment. The carrier wafer 810 is detached by dissolving the adhesive layer 812 attaching the carrier wafer 810 to the semiconductor wafer 830. Additionally, after dissolving the adhesive, a cleaning process may be performed to clean residue left after dissolving the adhesive. The cleaning process may include one or more rinsing processes that include applying solvent for the adhesive and isopropyl alcohol. After cleaning dies may be singulated from the semiconductor wafer 830. After the stress balance layer 852 is deposited, risk of warpage of the semiconductor wafer 830 or dies singulated from the semiconductor wafer 830 is reduced. Risk of warpage is reduced because the stress balance layer 852 counteracts the unbalanced stress between the substrate 820 and the active layer 816.

Although only one through silicon via is shown in FIGS. 8A-8E of course there can be multiple through silicon vias in a semiconductor wafer or semiconductor die.

A stress balance layer deposited on a wafer reduces the risk of wafer warpage due to stress unbalance on the wafer. Reducing wafer warpage is important to increase process margins and process yields. In one example, stress balance layers may be used in manufacturing of stacked ICs to prevent wafer warpage after release of the thinned die from a carrier wafer. Additionally, the deposition of a stress balance layer does not alter the stress of active layer on dies the wafer. Thus, the strain engineering of dies on the wafer is preserved.

Although the terminology “through silicon via” includes the word silicon, it is noted that through silicon vias are not necessarily constructed in silicon. Rather, the material can be any device substrate material.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor component, comprising:
a first substrate having a front side and a back side; and
a stress balance layer balancing stress in the semiconductor component.

2. The semiconductor component of claim 1, in which the stress balance layer is on a back side and comprises at least one of a silicon nitride film, a silicon carbide film, a silicon dioxide, a spin on glass, and a polymer.

3. The semiconductor component of claim 1, in which the stress balance layer comprises a multilayer film.

4. The semiconductor component of claim 1, further comprising:
an active layer on the front side, the active layer creating stress on the semiconductor component.

5. The semiconductor component of claim 4, in which stress in the stress balance layer is approximately equal to stress in the active layer.

6. The semiconductor component of claim 1, in which the first substrate comprises at least one through silicon via.

7. The semiconductor component of claim 1, in which the semiconductor component is a semiconductor die.

8. The semiconductor component of claim 1, in which the semiconductor component is a semiconductor wafer.

9. The semiconductor component of claim 1, in which the semiconductor component is incorporated into a memory device

10. A method of manufacturing a semiconductor wafer, the method comprising depositing a stress balance layer on the semiconductor wafer.

11. The method of claim 10, further comprising thinning the semiconductor wafer before depositing the stress balance layer to expose at least one through silicon via.

12. The method of claim 11, further comprising performing a silicon recess etch after thinning the semiconductor wafer.

13. The method of claim 10, further comprising releasing the semiconductor wafer from a carrier wafer after depositing the stress balance layer.

14. The method of claim 10, in which depositing the stress balance layer comprises depositing at least one of a silicon nitride layer, a silicon oxide layer, a silicon carbide layer, and a polymer.

15. The method of claim 14, in which depositing the stress balance layer comprises adjusting a composition of the stress balance layer to obtain a desired stress level.

16. The method of claim 10, in which the desired stress level is chosen to balance stresses on the semiconductor wafer.

17. The method of claim 10, in which depositing the stress balance layer comprises adjusting an ion bombardment parameter of the stress balance layer to obtain a desired stress level.

18. The method of claim 17, in which adjusting an ion bombardment parameter comprises adjusting a background pressure of plasma enhanced chemical vapor deposition (PECVD) deposition.

19. The method of claim 17, in which the desired stress level is chosen to balance stresses on the semiconductor wafer.

20. A semiconductor component, comprising:
a substrate having a front side and a back side;
an active layer on the front side, the active layer imposing stress on the substrate; and
means for balancing stress imposed by the active layer, the balancing means being disposed on the back side of the substrate.
